(19) United States
(12) Patent Application Publication
(10) Pub. No.: US 2011/0008550 A1
(43) Pub. Date: Jan. 13, 2011

(54) ATOMIC LAYER GROWING APPARATUS AND THIN FILM FORMING METHOD

(75) Inventors: Kazutoshi Murata, Okayama (JP); Keisuke Washio, Okayama (JP)

Correspondence Address: GLOBAL IP COUNSELORS, LLP, 1233 20TH STREET, NW, SUITE 700, WASHINGTON, DC, 20036-2680, US

(73) Assignee: MITSUI ENGINEERING & SHIPBUILDING CO., LTD, Chuo-ku, Tokyo (JP)

(21) Appl. No.: 12/863,565

(22) PCT Filed: Jan. 22, 2009
(86) PCT No.: PCT/JP2009/000240

§ 371 Date: Sep. 9, 2010

(30) Foreign Application Priority Data
Jan. 25, 2008 (JP) 2008-014647

(51) Int. Cl. C23C 16/509; C23C 16/00

(52) U.S. Cl. 427/569; 118/723 I

(57) ABSTRACT

An atomic layer growing apparatus includes a deposition container, a gas supply unit, and an exhaust unit. In the deposition container, an antenna array and a substrate stage are provided. The antenna array is formed by disposing a plurality of antenna elements in parallel, each of the antenna elements being configured by coating a rod-shaped antenna body with a dielectric material. The antenna array generates plasma using one of an oxidizing gas and a nitriding gas. The substrate is placed on the substrate stage. The gas supply unit alternately supplies the source gas and the oxidizing gas toward the substrate stage from a supply hole made in a sidewall of the deposition container when a film is formed on the substrate. The exhaust unit exhausts the source gas and one of the oxidizing gas and the nitriding gas, which are alternately supplied into the deposition container.

### TECHNICAL FIELD

The present invention relates to an atomic layer growing (hereinafter also abbreviated to ALD (Atomic Layer Deposition)) apparatus that forms a thin film in atomic layer units on a substrate and a thin-film forming method.

### BACKGROUND ART

In the ALD method that is one of thin-film forming techniques, two kinds of gases composed mostly of elements constituting a film to be formed are alternately supplied onto a deposition target substrate, and formation of a thin film in an atomic layer or a few atomic layers is repeated plural times on the substrate, thereby forming a film having a desired thickness. For example, a source gas containing Si and an oxidizing gas containing O are used when a SiO₂ film is formed on the substrate. A nitriding gas is used instead of the oxidizing gas when a nitride film is formed on the substrate.

In the ALD method, while the source gas is supplied, a source gas component only for one or several layers is adsorbed to a substrate surface, and the excess source gas does not contribute to the deposition. This is well known as deposition self-stopping action (self-limiting function).

The ALD method advantageously has both high step coverage and film-thickness controllability compared with a general CVD (Chemical Vapor Deposition) method, so that the ALD method is expected to be practically applied to formation of a capacitor of a memory element or an insulating film called “high-k gate”. Further, because the insulating film can be formed at a low temperature of about 300° C. in the ALD method, the ALD method is also expected to be applied to formation of a gate insulator film of a thin-film transistor in a display device such as a liquid crystal display in which a glass substrate is used.

A conventional ALD apparatus will be described below.

FIG. 7 is a schematic diagram illustrating an example of a configuration of the conventional ALD apparatus. Referring to FIG. 7, an ALD apparatus 50 includes a deposition container (deposition chamber) 12, a gas supply unit 14, and an exhaust unit 16.

The deposition container 12 is formed into a metallic hollow box shape and grounded. In the deposition container 12, an antenna array 28 including plural antenna elements 26 and a substrate stage 32 in which a heater 30 is incorporated are sequentially provided from an upper wall side toward a lower wall side. In the antenna array 28, a virtual plane formed by the plural antenna elements 26 which are disposed in parallel at predetermined intervals is provided in parallel with the substrate stage 32.

As illustrated in FIG. 8 that is a plan view from above, the antenna element 26 is a rod-shaped monopole antenna (antenna body) 39 made of a conductive material having a length of (2n+1)/4 times (n is 0 or a positive integer) a wavelength of high-frequency power, and the antenna element 26 is accommodated in a cylindrical member 40 made of a dielectric material. The high-frequency power generated by a high-frequency power supply unit 34 is distributed by a distributor 36 and supplied to each antenna element 26 through an impedance matching box 38, thereby generating plasma around the antenna element 26.

Each antenna element 26 is disclosed in Japanese Patent Application Laid-Open No. 2003-86581 proposed by the applicant. For example, the antenna element 26 is attached to a sidewall of the deposition container 12 while electrically insulated so as to be extended in a direction orthogonal to a gas flow direction of the oxidizing gas supplied toward a substrate stage 32 from a supply hole 20b. The antenna elements 26 are disposed in parallel at predetermined intervals, and the antenna elements 26 are disposed adjacent to each other such that power feeding positions of the antenna elements 26 are located in sidewalls opposite each other.

An operation during the deposition of the ALD apparatus 50 will be described below.

During the deposition, a substrate 42 is placed on an upper surface of the substrate stage 32. The substrate stage 32 is heated with the heater 30, and the substrate 42 placed on the substrate stage 32 is maintained at a predetermined temperature until the deposition is ended.

For example, when a SiO₂ film is formed on the substrate surface, after the deposition container 12 is horizontally evacuated with the exhaust unit 16, the source gas containing a Si component is horizontally supplied from the gas supply unit 14 into the deposition chamber 48 through a supply pipe 18a and a supply hole 20a made in a left wall of the deposition container 12. Therefore, the source gas is supplied to the surface of the substrate 42 and the source gas component is adsorbed to the surface of the substrate 42. At this point, the plasma is not generated by the antenna element 26.

Then, the supply of the source gas is stopped, and the excess source gas other than the source gas component adsorbed to the surface of the substrate 42 is horizontally exhausted from the deposition container 12 through an exhaust hole 24 made in a right wall of the deposition container 12 and an exhaust pipe 22 with the exhaust unit 16.

Then the oxidizing gas is horizontally supplied from the gas supply unit 14 into the deposition container 12 through a supply pipe 18b and the supply hole 20b made in the left wall of the deposition container 12. At the same time, high-frequency power is supplied from the high-frequency power supply unit 34 to each antenna element 26. As a result, the plasma is generated around each antenna element 26 using the oxidizing gas, and the source gas component adsorbed to the surface of the substrate 42 is oxidized.

Then, the supply of the oxidizing gas and the supply of the high-frequency power to the antenna element 26 are stopped, and the excess oxidizing gas that does not contribute to the oxidation and the reaction product are horizontally exhausted through the exhaust hole 24 made in the right wall of the deposition container 12 and the exhaust pipe 22 with the exhaust unit 16.

Thus, SiO₂ is formed in atomic layer units on the substrate 42 through a series of processes including the supply of the source gas→the exhaust of the excess source gas→the supply of the oxidizing gas→the exhaust of the excess oxidizing gas. The SiO₂ film having a predetermined thickness is formed on the substrate 42 by repeating the series of processes several times.

### DISCLOSURE OF THE INVENTION

As described above, the use of the plasma is widely proposed in order to enhance reaction activity in the deposition using the ALD method. In principle, it is believed that various plasma sources such as CCP (Capacitive-Coupled Plasma), IPC (Inductively Coupled Plasma), and ECR (Electron-Cyclotron Resonance Plasma) can be applied.

Although the high-density plasma is obtained by the IPC or the ECR, generally a pressure of the source gas is set to as low as 10 Pa or less. Accordingly, in the ALD method deposition in which the gas pressure becomes several pascals or more by the source gas supplied in a pulsing way, unfortunately it is difficult to stably generate plasma. In the CCP, although there is no restriction of the gas pressure, unfortunately the plasma density is intrinsically low.

Like the ALD apparatus 50 illustrated in FIG. 7, when the antenna array 28 is disposed above the substrate 42, the formed film is damaged by the plasma, which causes a problem in that film quality is degraded. Further, the film is deposited on the surface of the antenna element 26 at the same time as the film is formed on the surface of the substrate 42. Part of the film deposited on the surface of the antenna element 26 falls off, or dust or a reaction product (fine particle) produced in the gas phase becomes a particle, and there is a risk of contaminating the surface of the substrate 42 to degrade the film quality.

In view of the foregoing, an object of the invention is to provide an atomic layer growing apparatus that stably generates the high-density plasma to be able to enhance the reaction activity in the deposition using the atomic layer growing method, reduces the plasma damage of the formed film, and can reduce the contamination by the particle and a thin-film forming method.

### Means for Solving the Problems

To attain the object, the present invention provides an atomic layer growing apparatus that forms a thin film on a substrate. The apparatus includes:
(A) a deposition container in which an antenna array and a substrate stage are provided, the antenna array being formed by disposing a plurality of antenna elements in parallel, each of the antenna elements being configured by coating a rod-shaped antenna body with a dielectric material, the antenna array generating plasma using an oxidizing gas, the substrate being placed on the substrate stage;
(B) a gas supply unit that alternately supplies a source gas and the oxidizing gas toward the substrate stage of the deposition container from a supply hole made in a sidewall of the deposition container when a predetermined film is formed on the substrate; and
(C) an exhaust unit that exhausts the source gas and the oxidizing gas, which are alternately supplied into the deposition container.
(D) The antenna array is disposed in a space on an upstream side of a position of the substrate placed on the substrate stage in a gas flow direction of the oxidizing gas supplied toward the substrate stage from the supply hole.

The present invention also provides an atomic layer growing apparatus that forms a thin film on a substrate. The apparatus includes:
(E) a deposition container in which an antenna array and a substrate stage are provide, the antenna array being formed by disposing a plurality of antenna elements in parallel, each of the antenna elements being configured by coating a rod-shaped antenna body with a dielectric material, the antenna array generating plasma using a nitriding gas, the substrate being placed on the substrate stage;
(F) a gas supply unit that alternately supplies a source gas and the nitriding gas toward the substrate stage of the deposition container from a supply hole made in a sidewall of the deposition container when a predetermined film is formed on the substrate; and
(G) an exhaust unit that exhausts the source gas and the nitriding gas, which are alternately supplied into the deposition container.
(H) The antenna array is disposed in a space on an upstream side of a position of the substrate placed on the substrate stage in a gas flow direction of the nitriding gas supplied toward the substrate stage from the supply hole.

Preferably, each of the plurality of antenna elements is disposed in a direction parallel to a surface of the substrate stage, and a direction in which the plurality of antenna elements are arrayed is the direction parallel to the surface of the substrate stage or a direction perpendicular to the surface of the substrate stage.

Preferably, a lower wall of the deposition container including an upper surface of the substrate stage is formed so as to be flush when a predetermined film is formed on the substrate.

To attain the object, the present invention also provides a thin-film forming method of forming a thin film on a substrate in a deposition container. The method includes the steps of:
(I) supplying a source gas into the deposition container to adsorb a source gas component onto the substrate;
(J) exhausting the source gas from the deposition container;
(K) supplying an oxidizing gas toward the substrate in the deposition container, feeding electric power to an antenna array formed by disposing a plurality of antenna elements in parallel, each of the antenna elements being configured by coating a rod-shaped antenna body with a dielectric material, generating plasma using the oxidizing gas to produce active oxygen, causing the active oxygen to flow from one end of the substrate toward an opposite end, and oxidizing the source gas component adsorbed to the substrate using the active oxygen; and
(L) exhausting the oxidizing gas from the deposition container.

To attain the object, the present invention also provides a thin-film forming method of forming a thin film on a substrate in a deposition container. The method includes the steps of:
(M) supplying a source gas into the deposition container to adsorb a source gas component onto the substrate;
(N) exhausting the source gas from the deposition container;
(O) supplying a nitriding gas toward the substrate in the deposition container, feeding electric power to an antenna array formed by disposing a plurality of antenna elements in parallel, each of the antenna elements being configured by coating a rod-shaped antenna body with a dielectric material, generating plasma using the nitriding gas to produce active nitrogen, causing the active nitrogen to flow from one end of the substrate toward an opposite end, and nitriding the source gas component adsorbed to the substrate using the active nitrogen; and
(P) exhausting the nitriding gas from the deposition container.

According to the invention, by the use of the antenna array, the high-density plasma is stably generated, the neutral radical can substantially evenly be supplied to the large-area substrate, and the deposition reaction activity of the ALD method can be enhanced. The antenna array is disposed not above the substrate, but in a place away from the end portion of the substrate. Therefore, the plasma damage of the formed film is reduced, and the particles generated near the antenna array do not directly fall on the substrate, so that the contamination of the substrate can considerably be reduced.

### BRIEF DESCRIPTION OF THE DRAWINGS

FIG. 1 is a schematic diagram illustrating a configuration of an atomic layer growing apparatus according to an embodiment of the invention.

FIG. 2 is a schematic plan view illustrating a configuration of an antenna array in FIG. 1.

FIG. 3 is a graph illustrating a film thickness evenness of an alumina film formed on a substrate.

FIG. 4 is a graph illustrating a film refractive index of the alumina film formed on the substrate.

FIG. 5 is a sectional conceptual view of another example illustrating disposition of an antenna element.

FIGS. 6A and 6B are sectional conceptual views of still another example illustrating the disposition of the antenna element.

FIG. 7 is a schematic diagram illustrating an example of a configuration of a conventional atomic layer growing apparatus.

FIG. 8 is a schematic plan view illustrating a configuration of an antenna array in FIG. 7.

### BEST MODE FOR CARRYING OUT THE INVENTION

An atomic layer growing apparatus and a thin-film forming method according to an exemplary embodiment of the invention will be described in detail with reference to the drawings.

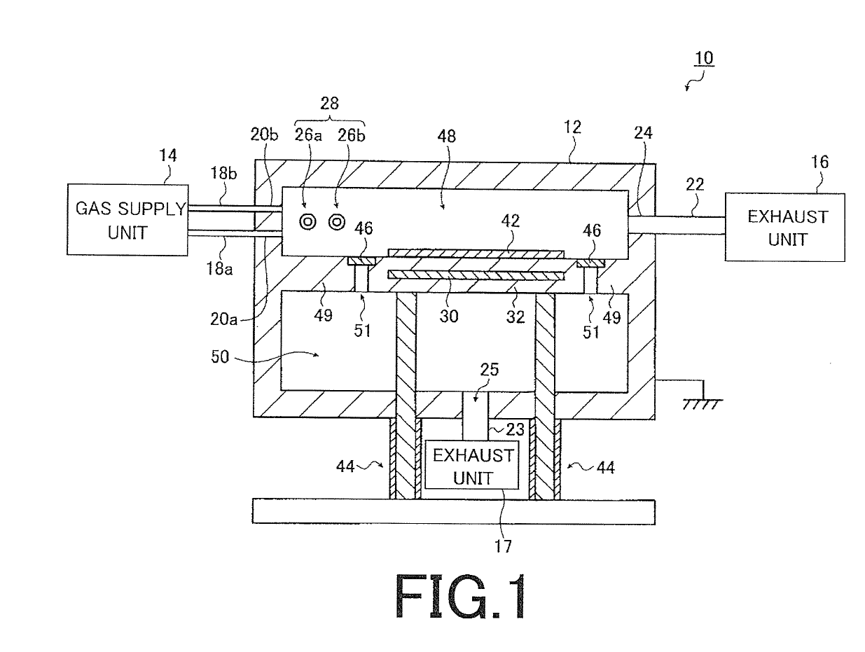

FIG. 1 is a schematic diagram illustrating a configuration of an ALD apparatus according to an embodiment of the invention. In an ALD apparatus 10 illustrated in FIG. 1, the ALD method is adopted, and two kinds of deposition gases (the source gas and the oxidizing gas or nitriding gas) composed mostly of elements constituting the film to be formed are alternately supplied onto the deposition target substrate. At this point, the plasma is generated in order to enhance the reaction activity, and the oxide film or nitride film of the source gas is formed in an atomic layer or a few atomic layers on the substrate. Assuming that one cycle is the above-described processing, the film having a desired thickness is formed by repeating the processing cycle plural times.

The ALD apparatus 10 includes a deposition container 12, a gas supply unit 14, and exhaust units 16 and 17 such as a vacuum pump. Although the case in which the oxide film is formed on the substrate 42 is described below by way of example, the case of the nitride film is described in the same way.

The gas supply unit 14 is connected to supply holes 20a and 20b made in one of the sidewalls (the left wall in FIG. 1) of the deposition container 12 (a later-mentioned deposition chamber 48) through supply pipes 18a and 18b. The gas supply unit 14 horizontally supplies the source gas into the deposition chamber 48 through the supply pipe 18a and the supply hole 20a, or horizontally supplies the oxidizing gas such as an oxygen gas and an ozone gas into the deposition chamber 48 through the supply pipe 18b and the supply hole 20b. The source gas and the oxidizing gas are alternately supplied.

On the other hand, the exhaust unit 16 is connected to an exhaust hole 24 made in the sidewall (the right wall in FIG. 1), which is opposite the left wall, of the deposition chamber 48 through an exhaust pipe 22. The exhaust unit 16 horizontally exhausts the source gas and oxidizing gas, which have been alternately supplied into the deposition chamber 48, through the exhaust hole 24 and the exhaust pipe 22. The exhaust unit 17 is connected to an exhaust hole 25, which is made in a lower wall of the deposition container 12 (the later-mentioned vacuum chamber (load lock chamber) 50), through an exhaust pipe 23. The exhaust unit 17 basically evacuates the vacuum chamber 50 through the exhaust hole 25 and the exhaust pipe 23.

Although not illustrated, an on-off valve (such as an electromagnetic valve) that controls communication between the gas supply unit 14 and the deposition chamber 48 is provided in the middle of the supply pipes 18a and 18b, and on-off valves that control communication between the exhaust units 16 and 17 and the deposition chamber 48 and vacuum chamber 50 are provided in the middle of the exhaust pipes 22 and 23, respectively.

When the gas is supplied from the gas supply unit 14 into the deposition chamber 48 of the deposition container 12, one of the on-off valves of the supply pipes 18a and 18b is opened to evacuate the gas supplied into the deposition chamber 48. When the vacuum chamber 50 of the deposition container 12 is evacuated, the on-off valve of the exhaust pipe 23 is opened.

The deposition container 12 is formed into a metallic hollow box shape and grounded. In the deposition container 12, an antenna array 28 including two antenna elements 26a and 26b is disposed on the left wall side onto which the oxidizing gas is supplied from the gas supply unit 14, and a substrate stage 32 incorporating a heater 30 is horizontally disposed in a space between the upper wall and the lower wall. In the antenna array 28, a virtual plane formed by each of the antenna elements 26a and 26b is disposed in parallel with the substrate stage 32.

The antenna array 28 generates the plasma using the oxidizing gas, and is disposed in a space between the substrate stage 32 and the left wall in which the supply hole 20b of the deposition chamber 48 is made, more strictly, in a space between the left wall in which the supply hole 20b is made and an end portion on the left wall side of the position at which the substrate 42 is placed on the substrate stage 32.

In other words, the antenna array 28 is disposed in a space on an upstream side in an oxidizing gas flow direction of the position at which the substrate 42 is placed on the substrate stage 32, more strictly, of an end portion of the position at which the substrate 42 is placed on the substrate stage 32, that is, of an end portion on the sidewall side of the deposition container 12 in which the supply hole 20b is made. The gas flow is formed such that the oxidizing gas is supplied toward the substrate stage 32 through the supply hole 20b, and that the oxidizing gas is exhausted through the exhaust hole 24.

That is, in the ALD apparatus 10, like a remote plasma method, the antenna array 28 generates the plasma in the place away from the substrate 42, and the oxygen radical (neutral radical) generated by the plasma diffuses in the whole region of the substrate 42.

The use of the antenna array 28 stably generates the high-density plasma to be able to substantially evenly supply the oxygen radical (active oxygen) to the large-area substrate 42, and enhance the oxidizing reaction activity during the deposition of the ALD method. The antenna array 28 is disposed not above the substrate 42, but in the place away from the end portion of the substrate 42. Therefore, the plasma damage of the formed film is reduced, and the particles generated near the antenna array 28 do not directly fall on the substrate 42, so that the contamination of the substrate 42 can considerably be reduced.

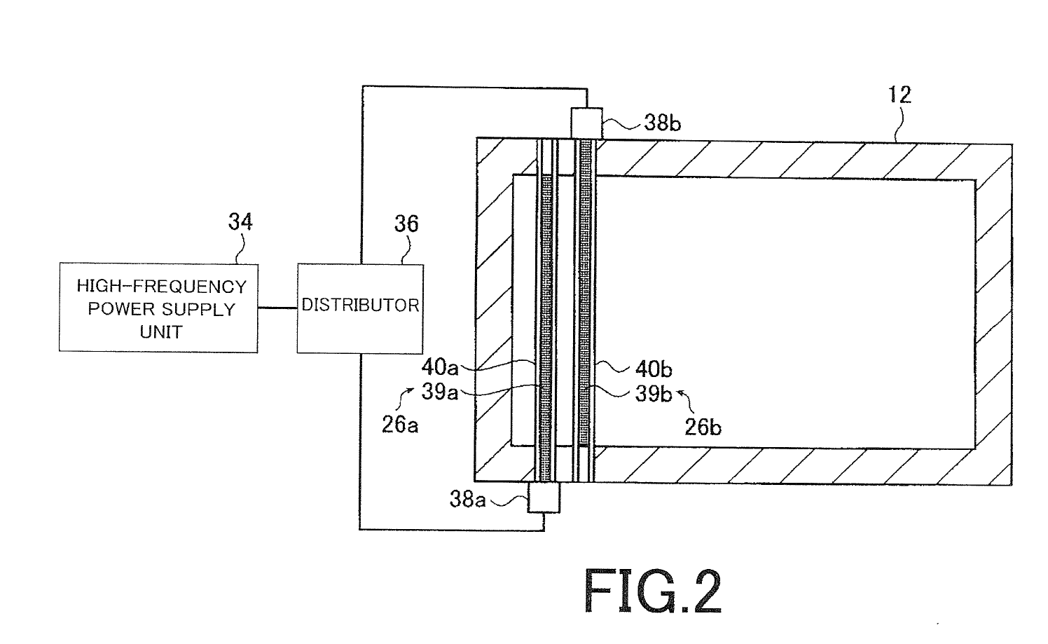

As illustrated in a plan view of FIG. 2, the high-frequency power (high-frequency current) of the VHF band (for example, 80 MHz) generated by the high-frequency power supply unit 34 is distributed by a distributor 36 and supplied to the antenna elements 26a and 26b through impedance matching boxes 38a and 38b. The impedance matching boxes 38a and 38b are used to correct impedance mismatch generated by changes in loads of the antenna elements 26a and 26b during the generation of the plasma while the frequency of the high-frequency power generated by the high-frequency power supply unit 34 is adjusted.

For example, the antenna elements 26a and 26b are formed by rod-shaped monopole antennas (antenna bodies) 39a and 39b made of a conductive material such as copper, aluminum, and platinum, and are accommodated in cylindrical members 40a and 40b made of a dielectric material such as quartz and ceramics. The antenna bodies 39a and 39b are coated with the dielectric material to adjust the capacitance and inductance as the antenna, so that the high-frequency power can efficiently be propagated along a longitudinal direction of the antenna bodies 39a and 39b to efficiently radiate an electromagnetic wave from the antenna elements 26a and 26b to the surroundings.

Each of the antenna elements 26a and 26b is extended in a direction orthogonal to the gas flow direction of the oxidizing gas supplied from the supply hole 20b toward the substrate stage 32, and is mounted on the sidewall of the deposition container 12 while electrically insulated. The antenna elements 26a and 26b are disposed in parallel at a predetermined interval, for example, at an interval of 50 mm such that power feeding positions of the antenna elements 26a and 26b disposed adjacent to each other are located in the sidewalls that are opposite each other (power feeding directions become reverse). Therefore, the electromagnetic wave is evenly formed over the whole virtual plane of the antenna array 28.

Electric field intensity in the longitudinal direction of the antenna elements 26a and 26b becomes zero at a supply end of the high-frequency power, and becomes the maximum in a leading end portion (a reverse end of the supply end). Accordingly, the power feeding positions of the antenna elements 26a and 26b are disposed in the sidewalls that are opposite each other, and the high-frequency powers are supplied to the antenna elements 26a and 26b from the directions opposite to each other, respectively, whereby the electromagnetic waves radiated from the antenna elements 26a and 26b are combined to form the even plasma and the film having the even thickness can be formed.

The antenna elements 26a and 26b are disposed in the direction parallel to the surface (the surface on which the substrate 42 is placed) of the substrate stage 32, and the direction in which the plural antenna elements 26a and 26b are arrayed is parallel to the surface of the substrate stage 32 on which the substrate is placed.

For example, in the antenna elements 26a and 26b, each of the antenna bodies 39a and 39b has a diameter of about 6 mm, and each of the cylindrical members 40a and 40b has a diameter of about 12 mm. Assuming that the high-frequency power of about 1500 W is supplied from the high-frequency power supply unit 34 while the deposition chamber 48 is set to the pressure of about 20 Pa, when antenna lengths of the antenna elements 26a and 26b are equal to (2n+1)/4 times (n is zero or a positive integer) the wavelength of the high-frequency power, a standing wave is produced to generate resonance, and the plasma is generated around the antenna elements 26a and 26b.

The substrate stage 32 has a size smaller than that of an inner wall surface of the deposition container 12. For example, the substrate stage 32 is formed by a rectangular metallic plate and vertically moves up and down with a lifting mechanism 44 such as a power cylinder. In the deposition container 12, a heater stopper (that is, a stopper for the substrate stage 42) 46 is provided with the deposition container 12 between a position at which the substrate stage 42 moves up and a protruded portion 49 that protrudes from the inner wall surface of the sidewall toward a central portion. L-shape steps are provided in an upper surface in an edge portion of the protruded portion 49 and an upper surface in an edge portion of the substrate stage 32. The L-shape step corresponds to a height of a side surface of the heater stopper 46.

When the substrate stage 32 moves up, the lower surface of the heater stopper 46 abuts on and have contact with the step portion of the upper surface in the edge portion of the substrate stage 32, a level of the upper surface of the substrate stage 32 is positioned so as to become substantially identical to (flush with) a level (that is, a level of the upper surface of the protruded portion 49) of the upper surface in the heater stopper 46. At this point, the inside of the deposition container 12 is divided into the deposition chamber 48 that is the space above the substrate stage 32 and the vacuum chamber 50 that is the space below the substrate stage 32, and the vacuum chamber 50 is evacuated with the exhaust unit 17 to tightly close the deposition chamber 48.

That is, as illustrated in FIG. 1, the upper wall of the deposition chamber 48 is formed flush, and the lower wall of the deposition chamber 48 including the upper surface of the substrate stage 42 is formed so as to be flush in forming a predetermined film on the substrate 42. It is not always necessary that the upper wall of the deposition chamber 48 be formed flush.

On the other hand, when the substrate stage 32 moves down, a predetermined gap 51 is formed between the lower surface of the heater stopper 46 and the step portion of the upper surface in the edge portion of the substrate stage 32. Moving down of the substrate stage 32 during exhausting the source gas and the like supplied to the deposition chamber 48 also allows the deposition gas supplied into the deposition chamber 48 to be exhausted from the gap 51 or from both the gap 51 and the exhaust hole 24. Because the size of the gap 51 is larger than that of the exhaust hole 24, the deposition gas can be exhausted from the deposition chamber 48 at high speed.

An operation during the deposition of the ALD apparatus 10 will be described below.

The case in which the alumina film (Al₂O₃) is formed on the surface of the substrate 42, 370 mm long by 470 mm wide, will be described below by way of example.

When the deposition starts, the substrate stage 42 moves down with the lifting mechanism 44, and the substrate 42 is placed on the upper surface of the substrate stage 32 in the vacuum chamber 50. Then, the substrate stage 32 moves up to the position at which the upper surface in the edge portion of the substrate stage 32 abuts on and have contact with the lower surface of the heater stopper 46, and the vacuum chamber 50 is evacuated with the exhaust unit 17 to tightly close the deposition chamber 48. The substrate stage 32 is heated with the heater 30, and the substrate 42 placed on the substrate stage 32 is maintained at a predetermined temperature, for example, at about 400° C. until the deposition is ended.

After the deposition chamber 48 is horizontally evacuated with the exhaust unit 16 to set the pressure of the deposition chamber 48 to about 2 to about 3 Pa, the source gas of trimethylaluminum ((CH₃)₃Al) gasified from a liquid raw material is supplied horizontally from the gas supply unit 14 into the deposition chamber 48 for about one second to set the pressure of the deposition chamber 48 to about 20 Pa. Therefore, the source gas component is adsorbed to the surface of the substrate 42. During adsorbing, the plasma is not generated by the antenna element 26.

Then, the supply of the source gas is stopped, and the excess source gas other than the source gas component adsorbed to the surface of the substrate 42 is horizontally exhausted for about one second from the deposition chamber 48 with the exhaust unit 16. At this point, the source gas supplied into the deposition chamber 48 may be exhausted with the exhaust unit 16 while a purge gas (inert gas) is supplied into the deposition chamber 48 from the gas supply unit 14 through the supply pipe 18a and the supply hole 20a.

Then the oxidizing gas is horizontally supplied for about one second from the gas supply unit 14 into the deposition chamber 48. Simultaneously, the high-frequency power supply unit 34 supplies the high-frequency power of about 1500 W to each of the antenna elements 26a and 26b. Therefore, the plasma is generated around the antenna elements 26a and 26b by the oxidizing gas. The plasma generates the oxygen radical. The oxygen radical of the plasma flows from one end of the substrate to the other end. The oxygen radical diffuses over the whole surface of the substrate 42, and the source gas component adsorbed to the surface of the substrate 42 is oxidized to form the alumina film.

Then, the supply of the oxidizing gas and the supply of the high-frequency power to the antenna elements 26a and 26b (that is, the generation of the plasma) are stopped, and the excess oxidizing gas that does not contribute to the oxidation and the reaction product are horizontally exhausted for about one second from the deposition chamber 48 with the exhaust unit 16. At this point, the oxidizing gas supplied into the deposition chamber 48 may be exhausted with the exhaust unit 16 while the purge gas is supplied into the deposition chamber 48 from the gas supply unit 14 through the supply pipe 18b and the supply hole 20b.

As described above, the alumina film is formed on the substrate 42 in atomic layer unit through the series of processes including the supply of the source gas→the exhaust of the excess source gas→the supply of the oxidizing gas→the exhaust of the excess oxidizing gas. The alumina film having a predetermined thickness is formed on the substrate 42 by repeating the series of processes several times.

The film thickness evenness of the alumina film formed through the processes and a film refractive index that becomes one of criteria of the film quality of the formed alumina film will be described below.

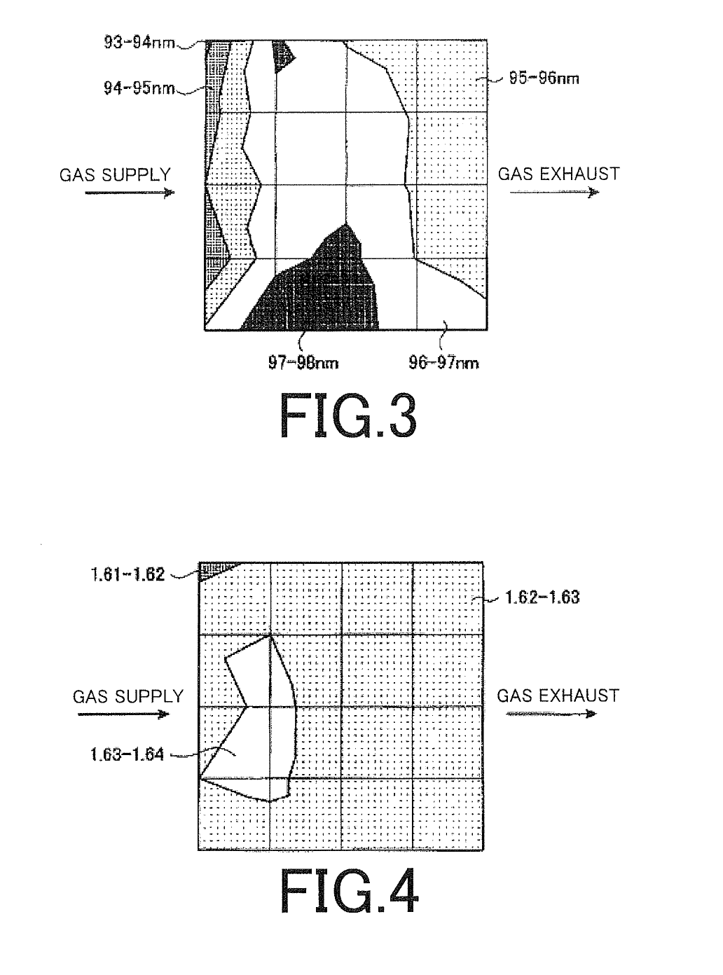

FIG. 3 is a graph illustrating the film thickness evenness of the alumina film that is formed on the substrate 42, 370 mm long by 470 mm wide, through the processes, and FIG. 4 is a graph illustrating the film refractive index of the alumina film. In FIG. 3, a horizontal side has a length of 470 mm, and a vertical side has a length of 370 mm. The graphs express the film thickness evenness and the film refractive index when the substrate 42 is viewed from above. In FIGS. 3 and 4, the left is the gas supply side (upstream side), and the right is the gas exhaust side (downstream side). In FIGS. 3 and 4, the upper side is the backside of FIG. 1, and the lower side is the front side.

As illustrated in the graph of FIG. 3, the film thickness of the substrate surface ranges from 93 to 98 nm, and the average film thickness of 25 points (in FIG. 3, an intersection of lines drawn into the grid shape and a square point of the substrate 42) on the substrate 42 is 96 nm. The film thickness varies about ±2.1%, and it is found that the film thickness evenness is sufficiently obtained.

As illustrated in the graph of FIG. 4, the film refractive index (a refractive index at an interface between the alumina film and the surface of the substrate 42) of the alumina film ranges from 1.61 to 1.64, and the average film refractive index of 25 points on the substrate 42 is about 1.626. The refractive index varies about ±0.5%, and it is found that the film refractive index is sufficiently obtained, in other words, it is found that the film quality is sufficiently obtained.

As a result, it can be demonstrated that the alumina film formed on the substrate 42 with the ALD apparatus 10 is excellent in both the film thickness evenness and the film refractive index (that is, film quality).

There is no limitation to the formed film in the invention. The source gas should appropriately be determined according to the formed film. The source gas may be supplied to the substrate from the sidewall side of the deposition container or supplied to the substrate from the upper wall side through a showerhead. On the other hand, the source gas may be exhausted from the sidewall side of the deposition container, from the lower wall side, or from both the sidewall side and the lower wall side.

For example, an oxidizing gas containing O is used as one of the reactive gases when the oxide film is formed on the substrate, and a nitriding gas containing N is used as one of the reactive gases when the nitride film is formed. When the oxide film is formed, the source gas is the reactive gas that is mainly composed of an element other than O in elements constituting the formed oxide film. When the nitride film is formed, the source gas is the reactive gas that is mainly composed of an element other than N in elements constituting the formed nitride film.

When the film is formed on the substrate, the pressure, the temperature, the processing time, and the gas flow rate in the deposition container should appropriately be determined according to the kind of the formed film, the sizes of the deposition container and substrate, and the like, and the invention is not limited to those of the embodiment. The invention is not limited in terms of the materials, shapes, and sizes of the deposition container and substrate stage.

The antenna array is provided in the space between the sidewall of the deposition container to which the gas supply unit horizontally supplies the oxidizing gas and the end portion, located at the position at which the substrate is placed on the substrate stage, on the sidewall side of the deposition container to which the oxidizing gas is supplied. There is no limitation to the number of antenna elements. However, in consideration of the evenness of the generated plasma, desirably the antenna elements are disposed such that the power feeding positions of the adjacent antenna elements are located in the sidewalls that are opposite each other. There is no particular limitation to the disposition and size of the antenna element.

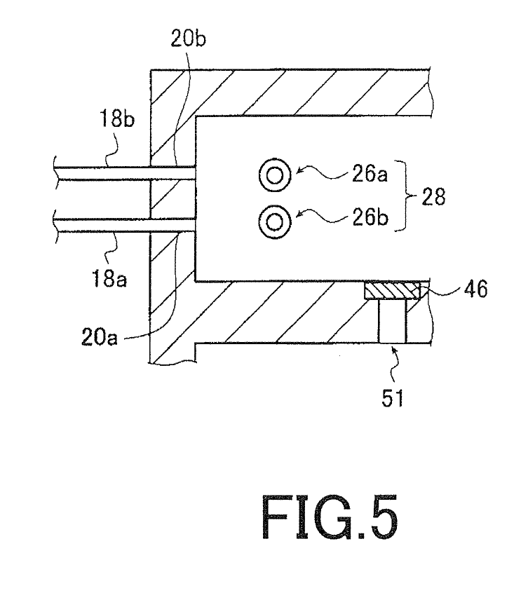

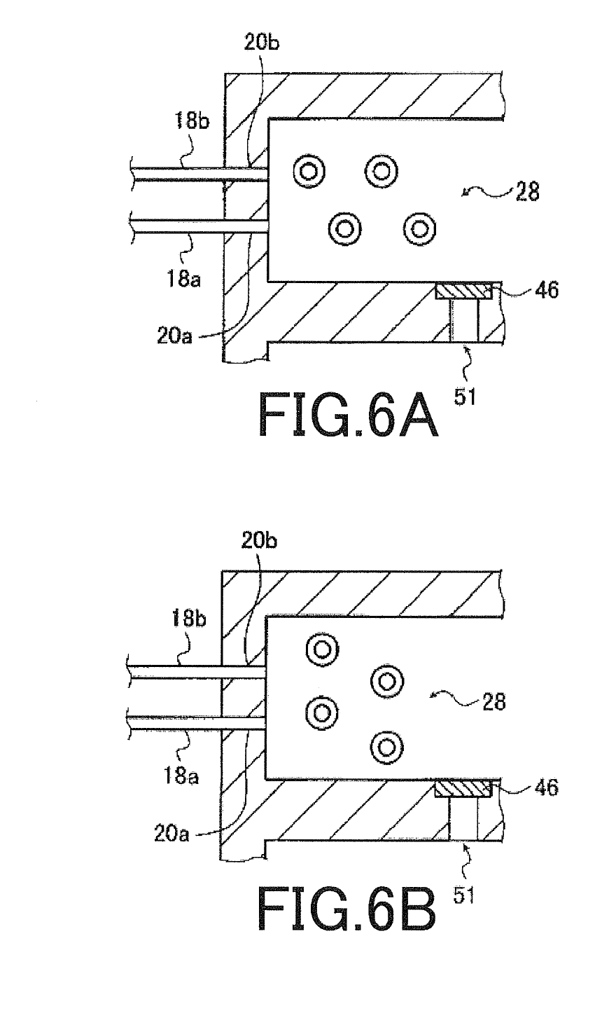

For example, the plural antenna elements may horizontally be disposed in a row as illustrated in FIG. 1, the antenna elements may vertically be disposed in a column as illustrated in FIG. 5, the antenna elements may horizontally be disposed while divided into at least two rows as illustrated in FIG. 6A, and the antenna elements may vertically be disposed while divided into at least two columns as illustrated in FIG. 6B. In these cases, in the rows or columns of the antenna elements, desirably the positions of the adjacent antenna elements are alternately located.

In the ALD apparatus of the invention, for example, the oxidizing gas is horizontally supplied into the deposition chamber, and the plasma is generated by the antenna array to obtain the oxygen radical. On the other hand, the plasma is not generated when the source gas is supplied into the deposition chamber. Therefore, the source gas may vertically be supplied from the upper wall side of the deposition container. Desirably a showerhead is provided in the space between the upper wall of the deposition container and the substrate stage such that the source gas does not directly blow to (strike on) the substrate while the source gas diffuses evenly.

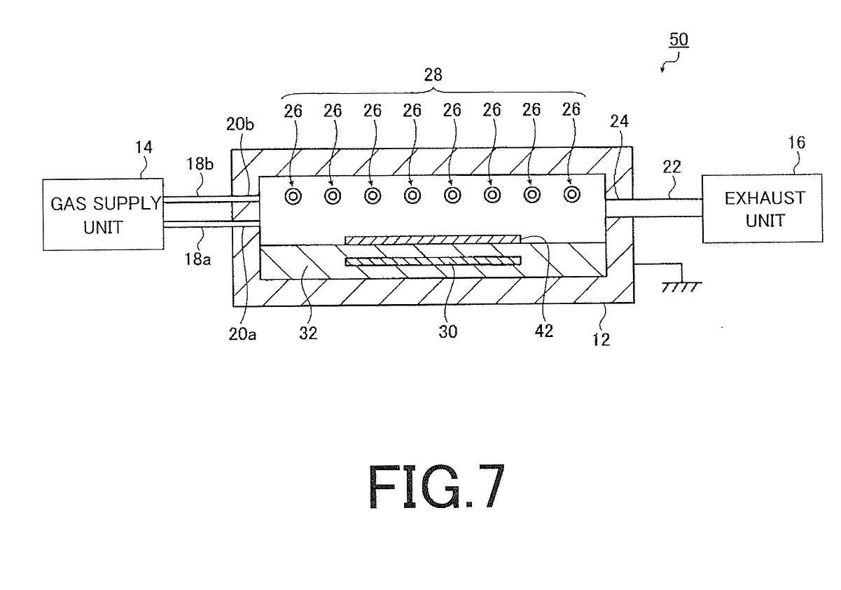

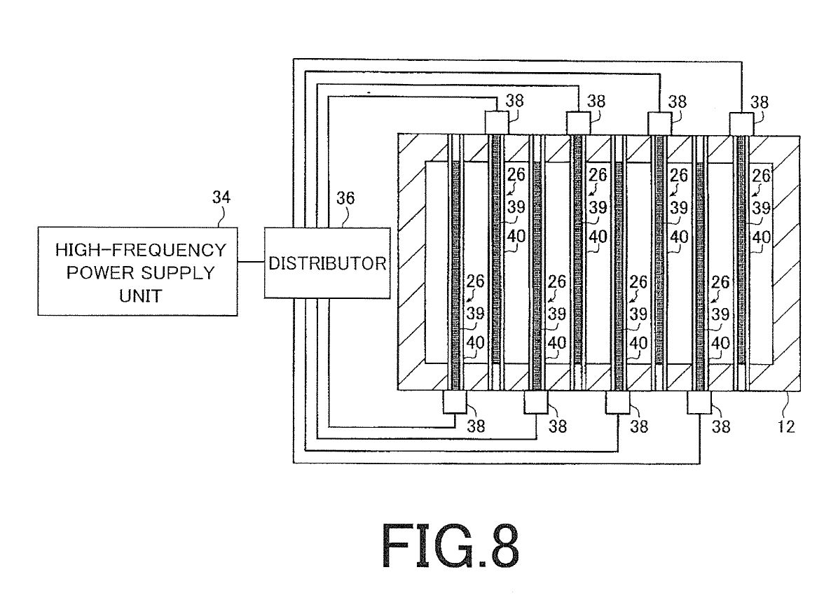

In the ALD apparatus of the invention, it is not always necessary to provide the lifting mechanism 44 and the vacuum chamber 50. In the configuration of the ALD apparatus of the invention in which the lifting mechanism 44 and the vacuum chamber 50 are eliminated, for example, the antenna array 28 in the conventional ALD apparatus 50 illustrated in FIGS. 7 and 8 is disposed not above the substrate stage 32 but in the space between the sidewall of the deposition container 12 and the substrate stage 32. In such cases, the deposition container 12 constitutes the deposition chamber 48.

The invention has been basically described above.

Although the atomic layer growing apparatus and thin-film forming method of the invention have been described in detail, the invention is not limited to the embodiment, and various modifications and changes may be made without departing from the scope of the invention.

### EXPLANATION OF LETTERS AND NUMERALS

10 and 50 atomic layer growing apparatus (ALD apparatus)
12 deposition container
14 gas supply unit
16 and 17 exhaust unit
18a and 18b supply pipe
20a and 20b supply hole
22 and 23 exhaust pipe
24 and 25 exhaust hole
26, 26a, and 26b antenna element
28 antenna array
30 heater
32 substrate stage
34 high-frequency power supply unit
36 distributor
38, 38a, and 38b impedance matching box
39, 39a, and 39b antenna body
40, 40a, and 40b cylindrical member
42 deposition target substrate (substrate)
44 lifting mechanism
46 heater stopper
48 deposition chamber
49 protruded portion
50 vacuum chamber
51 gap

1. An atomic layer growing apparatus that forms a thin film on a substrate, comprising:
a deposition container in which an antenna array and a substrate stage are provided, the antenna array being formed by disposing a plurality of antenna elements in parallel, each of the antenna elements being configured by coating a rod-shaped antenna body with a dielectric material, the antenna array generating plasma using one of an oxidizing gas and a nitriding gas, the substrate being placed on an upper surface of the substrate stage which is moveable up and down perpendicular to the upper surface;
a gas supply unit that alternately supplies a source gas and one of the oxidizing gas and the nitriding gas toward the substrate stage of the deposition container from a supply hole made in a sidewall of the deposition container when a predetermined film is formed on the substrate; and
an exhaust unit that exhausts the source gas and one of the oxidizing gas and the nitriding gas, which are alternately supplied into the deposition container,
wherein the antenna array is disposed in a space on an upstream side of a position of the substrate placed on the substrate stage in a gas flow direction of one of the oxidizing gas and the nitriding gas, and a stopper is provided in the deposition container, the stopper positioning the substrate stage to abut thereon and have contact therewith, dividing an inner room of the deposition container into an upper chamber and a lower chamber, and closing the upper chamber from the lower chamber when the substrate stage moves up.

2. (canceled)

3. The atomic layer growing apparatus according to claim 1, wherein each of the plurality of antenna elements is disposed in a direction parallel to a surface of the substrate stage, and a direction in which the plurality of antenna elements are arrayed is the direction parallel to the surface of the substrate stage.

4. The atomic layer growing apparatus according to claim 1, wherein each of the plurality of antenna elements is disposed in a direction parallel to a surface of the substrate stage, and a direction in which the plurality of antenna elements are arrayed is a direction perpendicular to the surface of the substrate stage.

5. The atomic layer growing apparatus according to claim 1, wherein a lower wall of the deposition container including the upper surface of the substrate stage is formed so as to be flush when a predetermined film is formed on the substrate.

6. A thin-film forming method of forming a thin film on a substrate placed on a substrate stage in a deposition container, comprising the steps of:
supplying a source gas into the deposition container to adsorb a source gas component onto the substrate placed on the substrate stage which is movable up and down;
exhausting the source gas from the deposition container;
supplying one of an oxidizing gas and a nitriding gas toward the substrate in the deposition container, feeding electric power to an antenna array formed by disposing a plurality of antenna elements in parallel, each of the antenna elements being configured by coating a rod-shaped antenna body with a dielectric material, generating plasma using one of the oxidizing gas and the nitriding gas to produce one of active oxygen and active nitrogen, causing one of the active oxygen and the active nitrogen to flow from one end of the substrate toward an opposite end, and oxidizing or nitriding the source gas component adsorbed to the substrate using one of the active oxygen and the active nitrogen; and
exhausting one of the oxidizing gas and the nitriding gas from the deposition container,
wherein a stopper is provided in the deposition container, the stopper positioning the substrate stage to abut thereon and have contact therewith, dividing an inner room of the deposition container into an upper chamber and a lower chamber, and closing the upper chamber from the lower chamber when the substrate stage moves up.

7. (canceled)

8. The thin-film forming method according to claim 6, wherein each of the plurality of antenna elements is disposed in a direction parallel to a surface of the substrate stage, and a direction in which the plurality of antenna elements are arrayed is the direction parallel to the surface of the substrate stage.

9. The thin-film forming method according to claim 6, wherein each of the plurality of antenna elements is disposed in a direction parallel to a surface of the substrate stage, and a direction in which the plurality of antenna elements are arrayed is a direction perpendicular to the surface of the substrate stage.
